(19) United States
(12) Patent Application Publication
(10) Pub. No.: US 2003/0058139 A1
(43) Pub. Date: Mar. 27, 2003

(54) Electronic devices having operating buttons

(75) Inventor: Kenichi Sakurai, Shirakawa-shi (JP)

Correspondence Address: CROWELL & MORING, L.L.P., P.O. Box 14300, Washington, DC, 20044-4300, US

(73) Assignee: Nippon Columbia Co., Ltd.

(21) Appl. No.: 10/285,645

(22) Filed: Nov. 1, 2002

Related U.S. Application Data
(63) Continuation of application No. 09/188,289, filed on Nov. 9, 1998, now abandoned.

(30) Foreign Application Priority Data
Nov. 7, 1997 (JP) 9-322427

(51) Int. Cl. H03M 11/00; H03K 17/94

(52) U.S. Cl. 341/22

(57) ABSTRACT

An electronic device having operating buttons is provided. The operating buttons can be identified only by touching on the operating button even under a condition being incapable of visually recognizing such as a case of operating the operating buttons by a visual handicapped person, a case of operating the operating buttons in a dark place, or the like.

In the electronic device having operating buttons for operating the device by closing and opening a switch with a pushing action, the operating buttons are provided in an operating surface of the buttons, and each of the buttons comprises at least one projecting portion or uneven portion which has a dimension equivalent to resolution of a human fingertip.

### BACKGROUND OF THE INVENTION

The present invention relates to an electronic device having operating buttons for operating the device by closing and opening a switch with a pushing action and particularly to an electronic device having operating buttons capable of being identified only by touching on an operating surface of the operating button of the electronic device.

Japanese Patent Application Laid-Open No.8-96647 discloses an operating button which is formed in such a shape that a function of the operating button can be understood and the shape of which can be identified only by touching with a fingertip.

Japanese Utility Model Application Laid-Open No.61-91829 discloses an operating button which has braille dots on an operating surface of the operating button so that a visually handicapped person may identify the operating button.

However, since the prior art described above does not take resolution of fingertip to adjacent dots (spatial discriminating ability) into consideration, it is required to recognize a shape or read braille by moving a finger so as to trace on the operating surface of the operating button in order to recognize with the fingertip.

Since the finger must be moved so as to trace on the operating surface of the operating button in order to recognize with the fingertip, there is a problem in that the switch is erroneously operated in a case where the switch is operated with a small pushing force.

The human has tactile spots in his fingertips and he judges by the tactile spots whether the fingertip is in contact with an object or not. The tactile spots in the finger tip as well as in the tip of tongue are denser in distribution and more sensitive in sense than in the other potions.

It is reported that resolution (spatial discriminating ability) of the fingertip is 2.5 mm to 4 mm. (“Physiology of Sense” (December 1980), edited by Robert F. Schmidt, published from Kinpou-do, pages 82 to 86)

Therefore, unless an interval between projections or an interval between edge lines of a depression opposite to each other provided on the operating surface of the operating button is larger than 2.5 mm to 4 mm, number of the projections or the depression cannot recognized only by touching on the operating surface with the fingertip.

Further, when number of the projections exceeds, for example, four, it is difficult to recognize number of the projections only by touching them with the fingertip even if a distance between two adjacent projections is large enough to be recognized.

### SUMMARY OF THE INVENTION

In order to solve the above problem, an object of the present invention is to provide an electronic device having operating buttons which can be identified only by touching on the operating button even under a condition being incapable of visually recognizing such as a case of operating the operating buttons by a visual handicapped person, a case of operating the operating buttons in a dark place, or a case of operating, for example, a portable equipment inside a bag.

The electronic device having operating buttons in accordance with the present invention is characterized by an electronic device having operating buttons for operating the device by closing and opening a switch with a pushing action, wherein each of the operating buttons comprises in an operating surface at least one projection or uneven portion which has a dimension equivalent to resolution of a human fingertip.

Further, the electronic device having operating buttons in accordance with the present invention is characterized by an electronic device having operating buttons for operating the device by closing and opening a switch with a pushing action, wherein each of the operating buttons comprises in an operating surface at least one projection or uneven portion having a dimension equivalent to resolution of human fingertip within a region capable of being covered with the bulb of human finger.

Further, the electronic device having operating buttons in accordance with the present invention is characterized by an electronic device having operating buttons for operating the device by closing and opening a switch with a pushing action, wherein each of the operating buttons comprises in an operating surface at least one projection or uneven portion having a dimension equivalent to resolution of human fingertip within a region capable of being covered with the bulb of human finger, number of the projections or uneven portions being not larger than four.

According to the present invention, since each of the operating buttons which comprises in an operating surface at least one projection having a dimension equivalent to resolution of human fingertip, the projection, number of the projecting portions or number of edge lines can be identified by the tactile spots of fingertip of forefinger or middle finger.

Further, according to another feature of the present invention, since the region of the operating surface of the operating button where at least one projecting portion, the projection or the uneven portion is arranged within a region capable of being covered with the bulb of forefinger or middle finger, the projection and number of the projections or number of the edge lines can be identified only by touching them with the bulb of forefinger or middle finger.

Therein, the detailed numerical values of the size equivalent to the resolution of the human fingertip and the region capable of being covered with the bulb of human finger are as follows.

That is, the electronic device having operating buttons in accordance with the present invention is characterized by an electronic device having operating buttons for operating the device by closing and opening a switch with a pushing action, wherein each of the operating buttons comprises in an operating surface at least one projection within a region, number of the projections being not larger than four, the region having a horizontal length not smaller than 3 mm and not larger than 12 mm and a vertical length not smaller than 3 mm and not larger than 20 mm when the operating surface is viewed from the front side, the projection having a diameter not smaller than 0.5 mm and not larger than 2 mm, an interval between the adjacent projections in the horizontal direction being not smaller than 2.5 mm and not larger than 10 mm when the operating surface is viewed from the front side, an interval between the adjacent projections in the vertical direction being not smaller than 2.5 mm and not larger than 18 mm when the operating surface is viewed from the front side.

Further, the electronic device having operating buttons in accordance with the present invention is characterized by an electronic device having operating buttons for operating the device by closing and opening a switch with a pushing action, wherein each of the operating buttons comprises in an operating surface a projecting portion or a depressing portion within a region, the region having a horizontal length not smaller than 3 mm and not larger than 12 mm and a vertical length not smaller than 3 mm and not larger than 20 mm when the operating surface is viewed from the front side, the projecting portion or the depressing portion having at least a pair of edge lines opposite to each other, an interval between the edge lines in the horizontal direction being not smaller than 2.5 mm and not larger than 10 mm when the operating surface is viewed from the front side, an interval between the edge lines in the vertical direction being not smaller than 2.5 mm and not larger than 18 mm when the operating surface is viewed from the front side.

Further, the electronic device having operating buttons in accordance with the present invention is characterized by an electronic device having operating buttons for operating the device by closing and opening a switch with a pushing action, wherein each of the operating buttons comprises in an operating surface a circular projecting portion or a circular depressing portion, a diameter of the circular projecting portion or the circular depressing portion being not smaller than 2.5 mm and not larger than 15 mm.

Further, the electronic device having operating buttons in accordance with the present invention is characterized by an electronic device having operating buttons for operating the device by closing and opening a switch with a pushing action, wherein each of the operating buttons comprises in an operating surface an annular projecting portion, a width of the annular portion being not smaller than 0.5 mm and not larger than 2 mm, an outer diameter of the annular portion being not smaller than 2.5 mm and not larger than 15 mm.

Further, the electronic device having operating buttons in accordance with the present invention is characterized by that the electronic device comprises a plurality of the operating buttons, and a height of the projecting portion or the depressing portion provided on the operating surface of the operating buttons is not smaller than 0.5 mm and not larger than 3 mm.

Further, the electronic device having operating buttons in accordance with the present invention is characterized by that the electronic device comprises a plurality of the operating buttons, and the operating buttons adjacent to each other have different shape of operating surface from each other.

Further, the electronic device having operating buttons in accordance with the present invention is characterized by that the electronic device comprises a plurality of the operating buttons, and the operating buttons adjacent to each other have different roughness of operating surface from each other.

Further, the electronic device having operating buttons in accordance with the present invention is characterized by that the electronic device comprises a plurality of the operating buttons, and the operating buttons adjacent to each other have different hardness of operating surface from each other.

Therefore, the region of the operating surface of the operating button where the plurality of projecting portions, the projections or the uneven portions are arranged is limited within a region capable of being covered with the bulb of forefinger or middle finger, that is, the region having a horizontal length not smaller than 3 mm and not larger than 12 mm and a vertical length not smaller than 3 mm and not larger than 20 mm when the operating surface is viewed from the front side.

In addition to this, since the interval between the projections or the projecting portions provided on the operating surface of the operating button; or the interval between the edge lines of the projecting portion or the depressing portion is set to 2.5 mm or more so as to be capable of being identified by the tactic tips of the fingertip, the projection and number of the projections or number of the edge lines can be identified only by touching them with the bulb of forefinger or middle finger.

Furthermore, since roughness on the operating surfaces of the adjacent operating buttons is changed by providing the operating button having a smooth surface like a mirror or the operating button having a rough surface like a file, the operating button can be identified only by touching them with the bulb of forefinger or middle finger.

Further, since hardness on the operating surfaces of the adjacent operating buttons is changed by providing the operating button having a hard surface like a metal or the operating button having an elastic surface like a rubber, the operating button can be identified only by touching them with the bulb of forefinger or middle finger.

### BRIEF DESCRIPTION OF THE DRAWINGS

FIG. 1 is a view showing an outer appearance of a voice guide apparatus having an embodiment of operating buttons in accordance with the present invention.

FIG. 2 is a block diagram showing the inner structure of the voice guide apparatus of FIG. 1.

FIG. 3 is a view showing the reverse surface of the voice guide apparatus of FIG. 1.

FIG. 4 is a perspective view showing an embodiment of operating buttons in accordance with the present invention.

FIG. 5 is a perspective view showing an embodiment of operating buttons in accordance with the present invention.

FIG. 6 is a perspective view showing an embodiment of operating buttons in accordance with the present invention.

FIG. 7 is a perspective view showing another embodiment of operating buttons in accordance with the present invention.

FIG. 8 is a perspective view showing a further embodiment of operating buttons in accordance with the present invention.

FIG. 9 is a perspective view showing a still further embodiment of operating buttons in accordance with the present invention.

FIG. 10 is a perspective view showing a still further embodiment of operating buttons in accordance with the present invention.

FIG. 11 is a block diagram showing another embodiment of a voice guide apparatus having an embodiment of operating buttons in accordance with the present invention.

### DESCRIPTION OF THE PREFERRED EMBODIMENTS

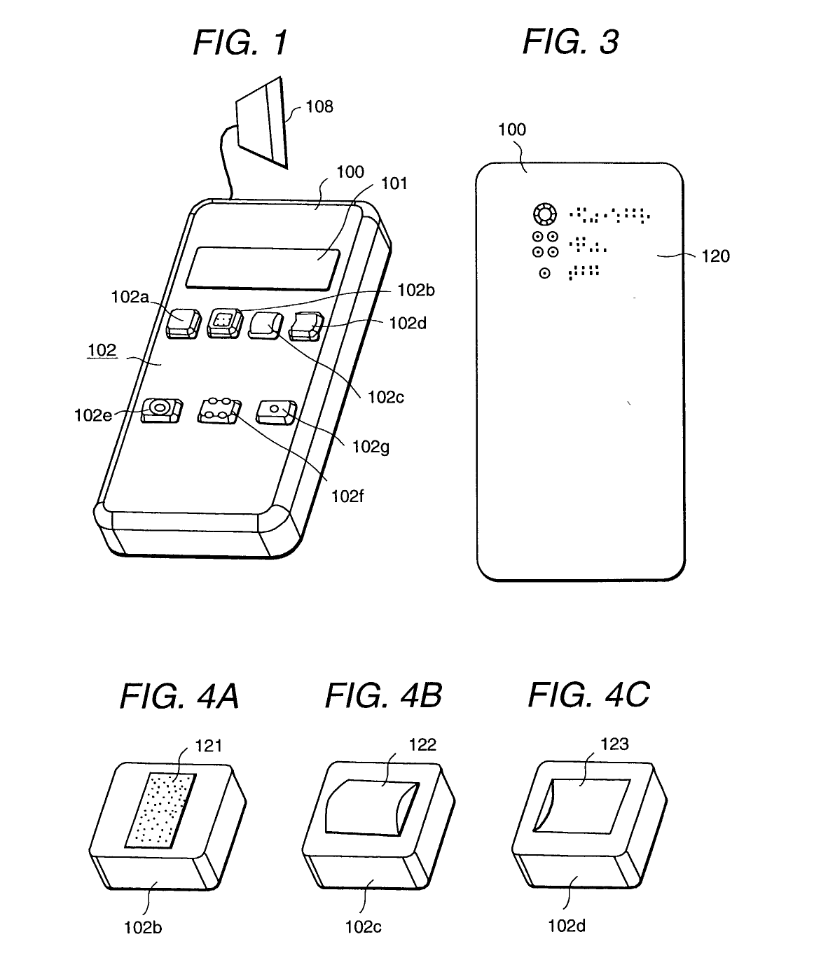

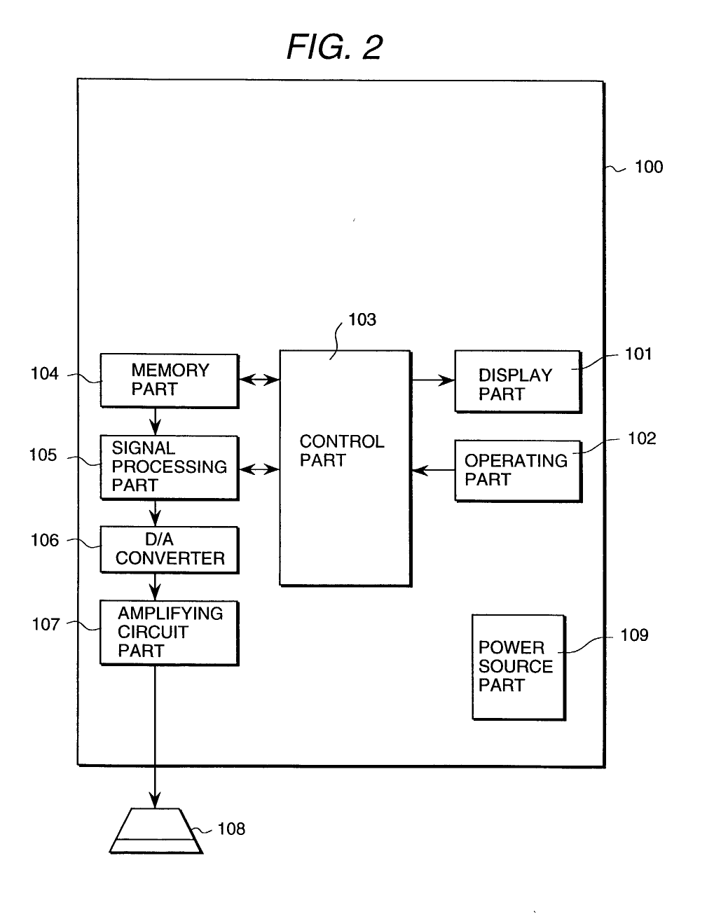

Embodiments of the present invention will be described below, referring to the accompanied figures. FIG. 1 is a view showing an outer appearance of a voice guide apparatus having an embodiment of operating buttons in accordance with the present invention. FIG. 2 is a block diagram showing the inner structure of the voice guide apparatus of FIG. 1. FIG. 3 is a view showing the reverse surface of the voice guide apparatus of FIG. 1.

The voice guide apparatus is lent to a person who needs voice guide, and when he approaches to an installed transmission apparatus, not shown, the voice guide apparatus receives a code signal transmitted from the transmission apparatus to read out voice guide information having a code agreeing with the transmitted code signal from a memory part 104 contained in the voice guide apparatus, and the voice guide information is reproduced by a reproducing part composed of a control part 103, a signal processing part 105, a D/A converter 106 and an amplifying circuit part 107, and then he can listen to the voice guide information through an earphone or the like.

In order to make it easy for a visual handicapped person to use the voice guide apparatus, the operating buttons have various surface shapes so that each of the operating buttons can be identified only by touching on it. In addition to this, a function set in each of the operating buttons is described in braille 120 corresponding to the surface shape of the operating button on the reverse side surface of the voice guide apparatus, as shown in FIG. 3.

Therefore, when the visual handicapped person operates the operating buttons, he can get information on the functions set to the operating buttons from the explanation corresponding to the surface shape of the operating button described in braille on the reverse surface of the voice guide apparatus.

Referring to FIG. 1, a display part 101 and seven operating buttons 102 are arranged in the front surface portion of the voice guide apparatus. The reference character 108 is an external earphone.

The operating buttons 102 are a reproducing button 102a for instructing the reproducing part to read out voice data from the memory part 104 with a built-in the voice guide apparatus 100 and to start reproduction of the voice data, a stop button 102b for instructing to stop the reproducing the voice data in the midway, a repeating button 102c for instructing repetitive reproduction of the reproducing the voice data, and an auxiliary button 102d provided as a spare.

Further, the operating buttons 102 are a present location button 102e by which he can know his present location, a telephone button 102f by which he can know a nearest place of a telephone from his present location, and a toilet button 102g by which he can know a nearest place of a toilet from his present location.

In FIG. 2, the display part 101 corresponds to the display part 101 in FIG. 1, and the operating part 102 corresponds to the operating buttons 102 in FIG. 1.

The control part 103 of FIG. 2 is a control part for performing control to read an operating signal of the reproducing button 102a of the operating part 102 and to read out the voice data stored in the memory part 104; and control to reproduce voice from the read-out voice data.

In addition to the above, the control part 103 performs control to display on the display part 101, and a microcomputer is used for the control part 103 in this embodiment.

The voice data read out from the memory part 104 is demodulated in the signal processing part 105 to signals which can be converted into analog signal in the digital-analog converter (D/A converter) 106. After converted to the analog signals by the D/A converter 106, the analog signals are amplified by the amplifying circuit 107 and then output to the external earphone 108.

A buttery is used for a power source part 109 because the present apparatus is a portable reproducing apparatus.

In FIG. 1, the reproducing button 102a, the stop button 102b, the repeating button 102c and the auxiliary button 102d each are formed in a square of 20 mm by 20 mm, and arranged in spacing between adjacent buttons so as to prevent the both buttons from being pushed at the same time.

Since frequency of using the present location button 102e, the telephone button 102f and the toilet button 102g is low, each of the present location button 102e, the telephone button 102f and the toilet button 102g has a projecting portion capable of stimulating a fingertip on the surface of the operating button so as to identify each of the operating button. Each of these buttons is formed in a rectangular shape having horizontal sides of 16 mm length and vertical sides of 10 mm length when the front surface of the voice guide apparatus is viewed from the front side, and these buttons are arranged in spacing between adjacent buttons so as to prevent the both buttons from being pushed at the same time.

Since the reproducing button 102a is frequently used, the operating surface of the reproducing button 102a is formed in a flat and smooth surface.

The operating surface of the stop button 102b has a rough surface 121 having a roughness of 0.1 mm as a file so as to be identified only by touching on the operating surface with the fingertip, as shown by the perspective view of FIG.4A.

The stop button 102b can be distinguished from the reproducing button 102a by the presence of rough surface since sinking of the skin surface above 0.01 mm can be recognized a difference between the two according to Robert F. Schmidt described previously.

The operating surface of the repeating button 102c has a projecting curved surface 122 formed of a part of a cylinder having a curvature of 7.5 R(mm) in the vertical direction and a horizontal length of 12 mm, as shown by the perspective view of FIG. 4B.

By forming the projecting curved surface 122 having a curvature not larger than the curvature of the bulb of the human finger of 7.5 R(mm), a contact area in contact with the bulb of finger becomes small and there are the edge lines spaced by 12 mm in the horizontal direction. Therefore, the edge line portion can be recognized when the button is touched with the bulb of finger.

By providing at least a pair of edge lines opposite to each other in a region having a horizontal length not smaller than 2.5 mm based on the tactic spot of the fingertip and not larger than 12 mm based on the width of the bulb of finger, the edge lines and number of the edge lines can be recognized only by touching them with the bulb of finger.

Further, when the bulb of finger is in contact with the curved surface 122 curved in the vertical direction since the curvature of the bulb of finger in the longitudinal direction is large, it is easy to recognize that the curved surface 122 is curved in the vertical direction because of the small contact area and large change in the contact pressure. In a case where the curved surface 122 is curved in the horizontal direction, it is difficult to recognize that the curved surface is curved because of the large contact area and small change in the contact pressure since the top portion of the curved surface is extended in the vertical direction which is the same direction of the longitudinal direction of the bulb of finger.

In the present embodiment, the curved surface 122 is curved in the vertical direction because of easiness of recognition by the fingertip, as described above.

Therefore, the repeating button 102c is clearly different from the two operating buttons described above in sense when the repeating button 122c is touched.

The operating surface of the auxiliary button 102d has a depressing curved surface 123 formed of a part of a cylinder having a curvature of 7.5 R in the vertical direction and a horizontal length of 12 mm, as shown by the perspective view of FIG. 4C.

Since the auxiliary button 102d has the edge line portions spaced 12 mm in the horizontal direction, the edge line portion can be recognized when the bulb of finger touches to the auxiliary button 102d. Further, the curved surface 123 having a depressing curvature not larger than the curvature of the bulb of the human finger of 7.5 R, the curvature is nearly equal to the curvature of the bulb of finger and the contact area becomes large when it is touched. Therefore, a sense of fitting to the finger can be obtained.

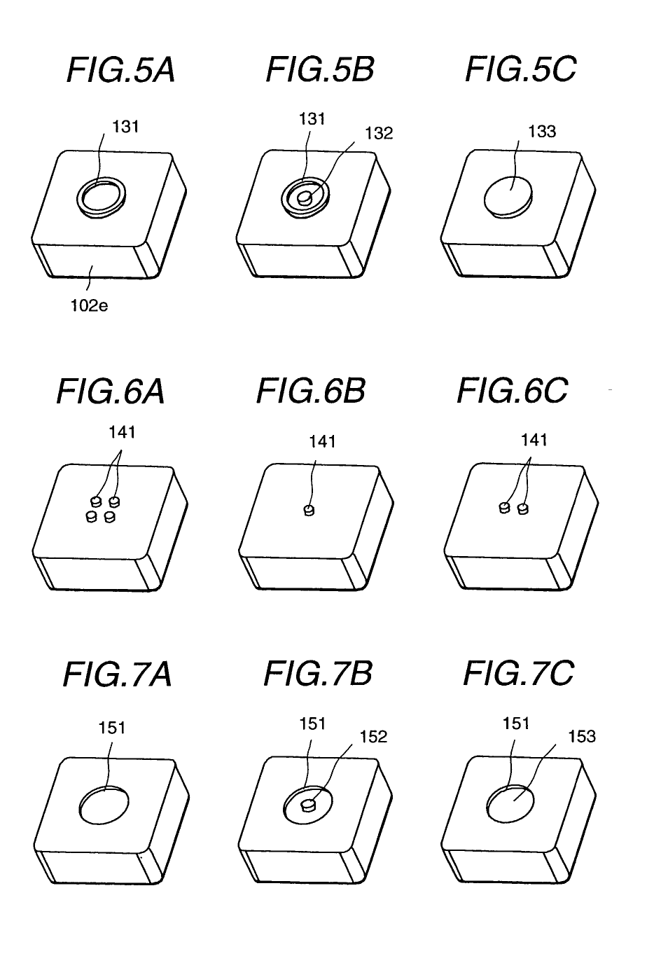

The operating surface of the present location button 102e has an annular projecting portion 131 having an outer diameter of 6 mm and an inner diameter of 4 mm and a height of 1.0 mm, as shown by the perspective view of FIG. 5A.

It is preferable that the annular projecting portion 131 has a diameter not smaller than 2.5 mm based on the resolution of the tactic spots of the fingertip and not larger than 15 mm based on the width of the tick of finger. Therefore, the outer diameter is set to 6 mm and the inner diameter is set to 4 mm in this embodiment.

Further, the height of the projecting portion 131 is not smaller than 0.5 mm which is determined from a lower limit for being formed through metal molding and not larger than 3 mm in taking operability of the operating surface into consideration.

In this embodiment, the height is set to 1.0 mm which can be easily formed through metal molding.

The width of the annular projecting portion 131 is not smaller than 0.5 mm which is determined from a lower limit for being formed through metal molding and not larger than 2 mm which is an upper limit incapable of being recognized to be two points by the tactic spots of the fingertip.

The width of the annular projecting portion 131 in this embodiment is set to 1.0 mm which can be easily formed through metal molding.

Therefore, the annular projecting portion 131 can be recognized as the annulus by touching the edge line portion with the bulb of finger.

Further, as shown in the perspective view of FIG. 5B, a projection 132 may be arranged in the center of the annular projecting portion 131 described above. The projection 132 has a diameter not smaller than 0.5 mm which can be formed through metal molding and not larger than 2 mm which is an upper limit incapable of being recognized to be two points by the tactic spots of the fingertip.

Further, as shown in the perspective view of FIG. 5C, a disk-shaped projection 133 having a diameter of 6 mm may be provided.

The telephone button 102f has four projections 141 arranged equally from the center of the operating surface of the operating button. The projection 141 has a diameter of 1 mm and a height of 1.0 mm, and an interval between the adjacent projections is 6 mm. The shape of the top end portion of the projection 141 may be either of a curved surface or a flat surface.

If the distance between the adjacent projections is larger than 2.5 mm, the projections can be recognized by the tactic spots of the fingertip, and by arranging four or less of the projections within a region of horizontally 12 mm and vertically 20 mm based on the dimension of the bulb of finger, number of the projections can be identified only by touching them with the bulb of finger.

The diameter of the projection 141 is not smaller than 0.5 mm which is determined from a lower limit for being formed through metal molding and not larger than 2 mm which is an upper limit incapable of being recognized to be two points by the tactic spots of the fingertip. The diameter of the projection in this embodiment is set to 1.0 mm which can be easily formed through metal molding and can be easily recognized as a circular projections with the fingertip.

Further, the height of the projection is not smaller than 0.5 mm which is determined from a lower limit for being formed through metal molding, and the height of the projection in this embodiment is set to 1.0 mm which can be easily formed through metal molding and can be easily recognized as a circular projections with the fingertip.

Therefore, since the diameter of the projection is set to 1.0 mm and the height of the projection is set to 1.0 mm and an interval between the adjacent projections is set to 6 mm in this embodiment, it is possible to recognize only by touching them with the bulb of finger that they are projections and number of the projection is four.

The toilet button 102g has one projection 141 in the center of the operating surface of the operating button, as shown in the perspective view of FIG. 6B. The projection 141 has a diameter of 1 mm and a height of 1.0 mm, and this is the same construction as the number 5 button in the conventional touch-tone telephone. Therefore, it is possible by touching the operating button with the bulb of finger to recognize that there is one projection.

Although number of the projections 141 of the toilet button 102g is one in this embodiment, number of the projections 141 may be two as shown in the perspective view of FIG. 6C. Further, number of the projections 141 may be three.

As another embodiment, a disk-shaped depressing portion may be provided on the operating surface of the operating button, as shown in the perspective view of FIG. 7.

The operating button of FIG. 7A has a disk-shaped depressing portion 151 having a diameter of 6 mm and a depth of 1.0 mm in the center of the operating surface of the operating button.

Since the edge line portion of the disk-shaped depressing portion 151 is 6 mm distant from the edge line in the opposite side, the disk-shaped depressing portion can be recognized as a disk-shaped depression by touching it with the bulb of finger.

The operating button of FIG. 7B has a disk-shaped depressing portion 151 having a diameter of 6 mm and a depth of 1.0 mm in the center of the operating surface of the operating button, and a projection 152 is provided in the center of the disk-shaped depressing portion 151.

By providing the projection 152 in the center of the disk-shaped depressing portion 151, it becomes easier by touching the operating button with the bulb of finger to recognize the disk-shaped depressing portion 151 than in the case of simply providing the disk-shaped depressing portion.

The operating button of FIG. 7C has a disk-shaped depressing portion 151 having a diameter of 6 mm and a depth of 1.0 mm in the center of the operating surface of the operating button, and the bottom surface of the depressing portion is formed in a projecting spherical surface 153. Therefore, the outer peripheral edge line portion of the disk-shaped depressing portion and the central portion of the disk-shaped depressing portion are in contact with the bulb of finger when touched the operating button. Although the operating button of FIG. 7C has the same depressing portion of 6 mm diameter, it can be identified because the sense of touch is different from the above two shapes.

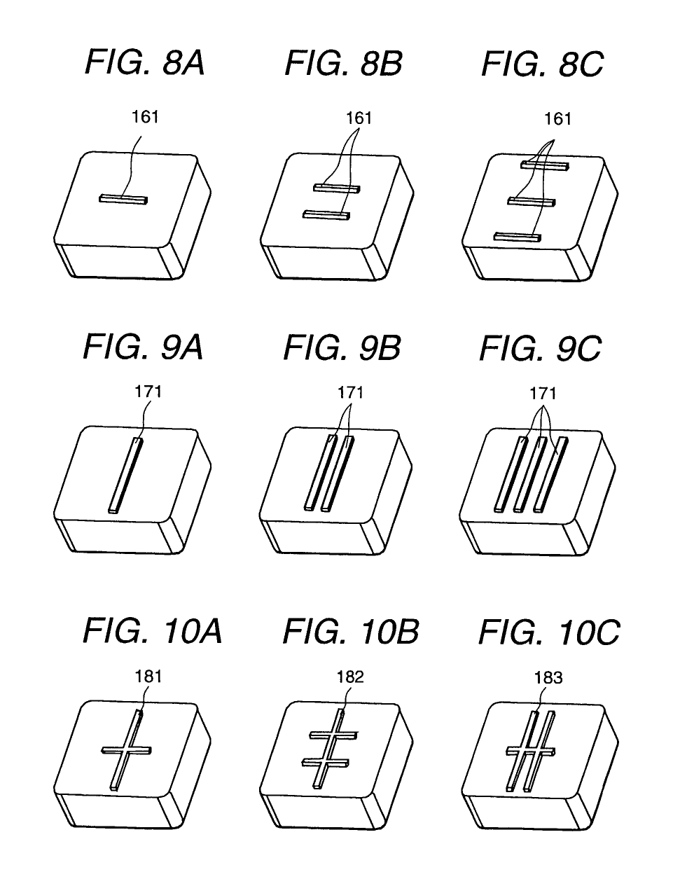

As a further embodiment, rectangular projecting portions may be provided on the operating surface of the operating button, as shown in the perspective view of FIG. 8.

The operating button of FIG. 8A has a rectangular projecting portion 161 extending in the horizontal direction in the center of the operating surface, and dimensions of the rectangular projecting portion 161 are a length of 12 mm, a width of 0.5 mm and a height of 1.0 mm.

When the rectangular projecting portion 161 is touched with the bulb of finger, it can be recognized that there is one rectangular projecting portion 161 extending in the horizontal direction.

The operating button of FIG. 8B has two rectangular projecting portions 161 by increasing number of the rectangular projecting portion shown in FIG. 8A to two, and the spacing between the two rectangular projecting portions is 6 mm.

When the rectangular projecting portions are touched with the bulb of finger, it can be recognized that there are two rectangular projecting portions 161 extending in the horizontal direction arranged in the vertical direction since the two rectangular projecting portions are spaced 6 mm in the vertical direction.

The operating button of FIG. 8C has three rectangular projecting portions 161 by increasing number of the rectangular projecting portion shown in FIG. 8A to three, and each spacing between the rectangular projecting portions is 6 mm.

Number of the above-mentioned projecting portions 161 may be increased up to four. If the spacing between the projecting portions 161 is above 2.5 mm, it can be recognized that there are four rectangular projecting portions 161 extending in the horizontal direction arranged in the vertical direction when the rectangular projecting portions are touched with the bulb of finger.

The width of the projecting portion 161 may be widened up to 2 mm. By doing so, each of the projecting portions 161 can be recognized as one projecting portion.

As a still further embodiment, rectangular projecting portions 171 extending in the vertical direction may be provided on the operating surface of the operating button, as shown in the perspective view of FIG. 9.

The operating button of FIG. 9A has a rectangular projecting portion 171 extending in the vertical direction in the center of the operating surface, and shape of the projecting portion 171 is a rectangle having a length of 20 mm, a width of 0.5 mm and a height of 1.0 mm.

The operating button of FIG. 9B has two rectangular projecting portions 171 by increasing number of the rectangular projecting portion shown in FIG. 8A to two, and the spacing between the two rectangular projecting portions arranged in the horizontal direction is 6 mm.

The operating button of FIG. 9C has three rectangular projecting portions 171 by increasing number of the rectangular projecting portion shown in FIG. 8A to three, and each spacing between the rectangular projecting portions arranged in the horizontal direction is 3 mm.

As a still further embodiment, a crossing rectangular projecting portion 181 having rectangles crossing each other at right angle may be provided on the operating surface of the operating button, as shown in the perspective view of FIG. 10.

The crossing rectangular projecting portion 181 is formed by combining the projecting portion 161 and the projecting portion 171 explained in FIG. 8 and FIG. 9. The operating button of FIG. 10A has a projecting portion 181 composed of two rectangles crossing each other at right angle on the operating surface of the operating button.

The operating button of FIG. 10B has a projecting portion 182 composed of two rectangular projecting portions 161 extending in the horizontal direction and vertically arranged in parallel with a spacing of 6 mm and a rectangular projecting portion 171 crossing with the two rectangular projecting portions 161 at right angle on the operating surface of the operating button.

The operating button of FIG. 10C has a projecting portion 183 composed of two rectangular projecting portions 171 extending in the vertical direction and horizontally arranged in parallel with a spacing of 3 mm and a rectangular projecting portion 161 crossing with the two rectangular projecting portions 171 at right angle on the operating surface of the operating button.

As shown in FIG. 10, by changing the combination of the rectangular projecting portions provided on the operating surface of the button, it is possible to increase number of kinds of operating buttons which can be identified only by touching on the operating button.

Although the above embodiments are described under assumption that the shape of the projecting portions are rectangular, the shape of the projection portions is not limited to rectangular. For example, semi-cylindrical projections may be applicable.

Further, hardness of the operating surface may be varied by forming a metal plate such as an aluminum plate having a bulbness of approximately 1.0 mm or rubber having a high elasticity in the shape of the projecting portion described above and attaching it in the operating surface of the operating button.

Furthermore, the operating button may be made of metal, plastic or rubber. By making the operating button different in hardness or feel of a material from the adjacent buttons, the button may be identified from the difference of the hardness or the feel of the material.

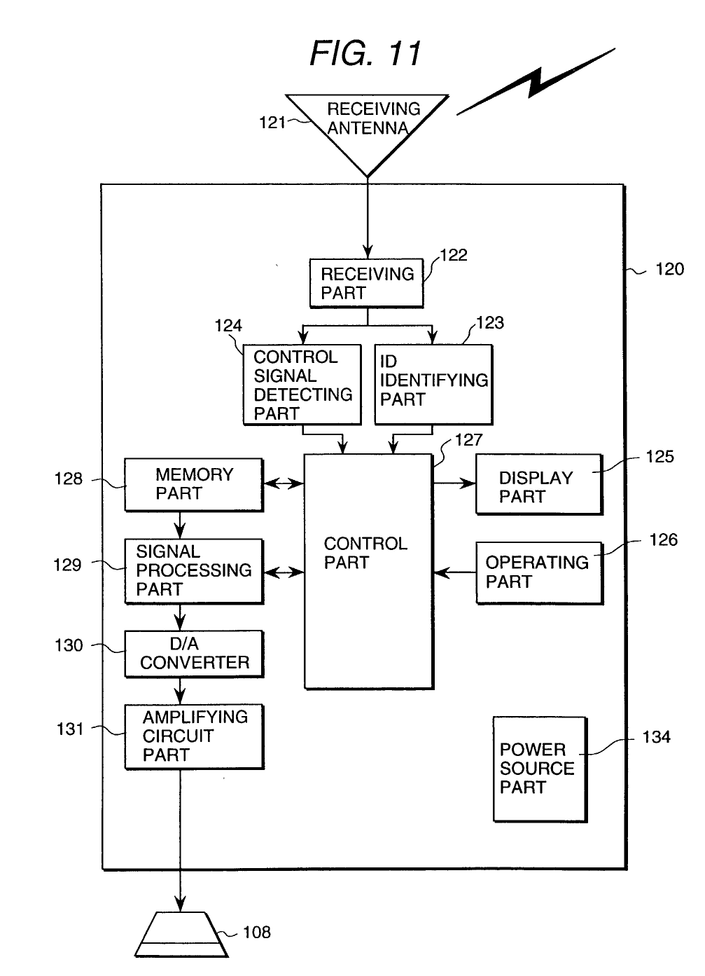

FIG. 11 shows another embodiment of a voice guide apparatus having an embodiment of operating buttons in accordance with the present invention which receives an input of a guide number using an radio wave as a wireless communication means.

The voice guide apparatus of FIG. 11 is a voice guide apparatus storing voice data of voice guide in the memory part. A different point of the voice guide apparatus from the voice guide apparatus of FIG. 2 is that this voice guide apparatus is constructed so as to successively select explanations stored with a hierarchy structure using one operating button in the voice guide apparatus, whereas the input means of the voice guide apparatus of FIG. 2 is only the operating button of the operating part 102 in the main apparatus. When the voice guide apparatus of FIG. 11 receives and identifies a signal of a guide number contained in a wireless radio wave transmitted from an external of the voice guide apparatus, the voice data stored in the IC memory is read out and the explanation is reproduced.

A receiving antenna 121 is a built-in antenna for receiving the wireless radio wave transmitted from the external of the voice guide apparatus. A receiving part 122 is a circuit unit for demodulating the received radio wave, and an ID identifying part 123 is a circuit for identifying an ID number corresponding to the guide number from the signal demodulated in the receiving part 122. A control signal detecting part 124 is a circuit for detecting a control signal to control operation of the voice guide apparatus.

A control part 127 performs control of retrieving a guide number corresponding to the ID number using the ID number demodulated by the receiving part 122 and output from the ID identifying part 123, and reading out a file of voice data stored in the memory part 128, and reproducing voice from the read-out voice data, and further operating the voice guide apparatus by deciphering the control signal output from the control signal detecting part 124.

In addition, the control part 127 performs control of displaying the guide number to the displaying part 125 and operating the voice guide apparatus by detecting operation of the operating button from the operating part 126.

In this embodiment, a microcomputer is used as the control part 127.

In this embodiment, an explanation in a first step is automatically reproduced by an instruction of the control signal described above. That is, when the ID number is identified, only the explanation in the first step is automatically reproduced without pushing a reproducing button. Therefore, a person having the voice guide apparatus with him can know what an exhibit is. When he wants to know detailed explanations, he pushes plural times the operating button provided in the operating part 126 to read out files of the voice data corresponding to the detailed explanations after the second steps, and thus he can successively listen to the detailed explanations.

The signal processing part 129, the D/A converting part 130, the amplifying circuit part 131, the earphone part 108, the power source part 134, the displaying part 125 and the operating part 126 are the same as those in FIG. 1 described previously. Therefore, the explanation on them is omitted here.

In this embodiment, the control part 127 stores a corresponding table relating the above-mentioned control signal with the ID number in the memory. Therefore, although the control signal is not contained in the transmitted radio wave, the control part 127 can perform a predetermined control by performing checking operation using the corresponding table stored in the memory when the ID number is received.

Further, by the control signal using the wireless communication means, it is not necessary to provide a guide number input key and a reproducing button in the main body of the voice guide apparatus. Furthermore, by constructing operating buttons in a wire remote control type and eliminating the operating buttons from the operating panel of the main body of the voice guide apparatus, operating buttons to be operated can be removed from the main body of reproducing apparatus.

In addition to the wireless communication means using radio wave in the embodiments described above, the wireless communication means using light such as infrared rays or ultrasonic waves may be employed.

According to the present invention, since the projecting portion or the depressing portion is provided on the operating surface of the operating button in taking the resolution of the tactic spots in the fingertip into consideration, shape and number of the projecting portion or the depressing portion provided on the operating surface can be recognized only by touching the operating button without tracing the fingertip on the operating surface.

Further, since roughness of the operating surface of the operating buttons is varied from roughness of the operating surface of the adjacent operating buttons, the operating button can be recognized only by touching the button by the bulb of finger.

Furthermore, since hardness of the operating surface of the operating buttons is varied from hardness of the operating surface of the adjacent operating buttons, the operating button can be recognized only by touching the button by the bulb of finger.

What is claimed is:

1. An electronic device having operating buttons for operating the device by closing and opening a switch with a pushing action, wherein
each of said operating buttons comprises in an operating surface at least one stimulating portion, said stimulating portion being any one of a projecting portion and an uneven portion which has a dimension equivalent to resolution of a human fingertip.

2. An electronic device having operating buttons for operating the device by closing and opening a switch with a pushing action, wherein
each of said operating buttons comprises in an operating surface at least one stimulating portion within a region capable of being covered with the bulb of human finger, said stimulating portion being any one of a projecting portion and an uneven portion which has a dimension equivalent to resolution of human fingertip.

3. An electronic device having operating buttons for operating the device by closing and opening a switch with a pushing action, wherein
each of said operating buttons comprises in an operating surface at least one stimulating portion within a region capable of being covered with the bulb of human finger, number of said stimulating portions being not larger than four, said stimulating portion being any one of a projecting portion and an uneven portion which has a dimension equivalent to resolution of human fingertip.

4. An electronic device having operating buttons for operating the device by closing and opening a switch with a pushing action, wherein
each of said operating buttons comprises in an operating surface at least one projecting portion within a region, number of said projecting portion being not larger than four, said region having a horizontal length not smaller than 3 mm and not larger than 12 mm and a vertical length not smaller than 3 mm and not larger than 20 mm when the operating surface is viewed from the front side, said projecting portion having a diameter not smaller than 0.5 mm and not larger than 2 mm, an interval between said adjacent projecting portions in the horizontal direction being not smaller than 2.5 mm and not larger than 10 mm when the operating surface is viewed from the front side, an interval between said adjacent projecting portions in the vertical direction being not smaller than 2.5 mm and not larger than 18 mm when the operating surface is viewed from the front side.

5. An electronic device having operating buttons for operating the device by closing and opening a switch with a pushing action, wherein
each of said operating buttons comprises in an operating surface at least one stimulating portion within a region, said stimulating portion being any one of a projecting portion and a depressing portion, said region having a horizontal length not smaller than 3 mm and not larger than 12 mm and a vertical length not smaller than 3 mm and not larger than 20 mm when the operating surface is viewed from the front side, said stimulating portion having at least a pair of edge lines opposite to each other, an interval between said edge lines in the horizontal direction being not smaller than 2.5 mm and not larger than 10 mm when the operating surface is viewed from the front side, an interval between said edge lines in the vertical direction being not smaller than 2.5 mm and not larger than 18 mm when the operating surface is viewed from the front side.

6. An electronic device having operating buttons for operating the device by closing and opening a switch with a pushing action, wherein
each of said operating buttons comprises in an operating surface at least one stimulating circular portion, said stimulating circular portion being any one of a projecting circular portion and a depressing circular portion, a diameter of said stimulating circular portion being not smaller than 2.5 mm and not larger than 15 mm.

7. An electronic device having operating buttons for operating the device by closing and opening a switch with a pushing action, wherein
each of said operating buttons comprises in an operating surface at least one annular projecting portion, a width of said annular portion being not smaller than 0.5 mm and not larger than 2 mm, an outer diameter of said annular projecting portion being not smaller than 2.5 mm and not larger than 15 mm.

8. An electronic device having operating buttons according to any one of claim 6 and claim 7, a projection having a diameter not smaller than 0.5 mm and not lager than 2 mm is provided at a center of said stimulating circular portion and said annular projecting portion.

9. An electronic device having operating buttons for operating the device by closing and opening a switch with a pushing action, wherein
each of said operating buttons comprises in an operating surface at least one stimulating portion within a region, said region having a horizontal length not smaller than 3 mm and not larger than 12 mm and a vertical length not smaller than 3 mm and not larger than 20 mm when the operating surface is viewed from the front side, said stimulating portion being any one of a projecting portion and a depressing portion which are formed of a part of any one of a sphere and a cylinder having a curvature of curved surface not larger than 7.5 R.

10. An electronic device having operating buttons for operating the device by closing and opening a switch with a pushing action, wherein
each of said operating buttons comprises in an operating surface at least one projecting portion arranged nearly in parallel within a region, said projecting portion having any one of a rectangular-shape and a semi-cylinder-shape, number of said projecting portions being not larger than four, said region having a horizontal length not smaller than 3 mm and not larger than 12 mm and a vertical length not smaller than 3 mm and not larger than 20 mm when the operating surface is viewed from the front side, said projecting portion having a length not smaller than 3 mm and not larger than 20 mm and a width not smaller than 0.5 mm and not larger than 2 mm, an interval between said adjacent projecting portions in the horizontal direction being not smaller than 2.5 mm and not larger than 10 mm when the operating surface is viewed from the front side, an interval between said adjacent projecting portions in the vertical direction being not smaller than 2.5 mm and not larger than 18 mm when the operating surface is viewed from the front side.

11. An electronic device having operating buttons for operating the device by closing and opening a switch with a pushing action, wherein
each of said operating buttons comprises in an operating surface two projecting portions crossing to each other at right angle within a region, said projecting portion having any one of a rectangular-shape and a semi-cylinder-shape, said region having a horizontal length not smaller than 3 mm and not larger than 12 mm and a vertical length not smaller than 3 mm and not larger than 20 mm when the operating surface is viewed from the front side, said projecting portion having a length in the horizontal direction not smaller than 3 mm and not larger than 12 mm; and a length in the vertical direction not smaller than 3 mm and not larger than 20 mm; and a width not smaller than 0.5 mm and not larger than 2 mm when the operating surface is viewed from the front side.

12. An electronic device having operating buttons for operating the device by closing and opening a switch with a pushing action, wherein
each of said operating buttons comprises in an operating surface at least one cross projecting portion within a region, number of said cross projecting portions being not larger than four, said region having a horizontal length not smaller than 3 mm and not larger than 12 mm and a vertical length not smaller than 3 mm and not larger than 20 mm when the operating surface is viewed from the front side, said cross projecting portions being composed of at least one first projecting portion arranged nearly in parallel and at least one second projecting portion respectively crossing to said first projecting portion at right angle, said first projecting portion and said second projecting portion having any one of a rectangular-shape and a semi-cylinder-shape, said first projecting portion and said second projecting portion having a length in the horizontal direction not smaller than 3 mm and not larger than 12 mm; a length in the vertical direction not smaller than 3 mm and not larger than 20 mm; and a width not smaller than 0.5 mm and not larger than 2 mm when the operating surface is viewed from the front side.

13. An electronic device according to any one of claim 1 to claim 3, wherein a height of any one of said stimulating portion provided on the operating surface of said operating buttons is not smaller than 0.5 mm and not larger than 3 mm.

14. An electronic device according to any one of claim 1 to claim 12, which comprises a plurality of said operating buttons, and the operating buttons adjacent to each other have different shape of operating surface from each other.

15. An electronic device according to any one of claim 1 to claim 12, which comprises a plurality of said operating buttons, and the operating buttons adjacent to each other have different roughness of operating surface from each other.

16. An electronic device according to any one of claim 1 to claim 11, which comprises a plurality of said operating buttons, and the operating buttons adjacent to each other have different hardness of operating surface from each other.
